(19) United States
(12) Patent Application Publication
(10) Pub. No.: US 2025/0140541 A1
(43) Pub. Date: May 1, 2025

(54) REAL-TIME PLASMA MEASUREMENT AND CONTROL

(71) Applicant: Applied Materials, Inc., Santa Clara, CA (US)

(72) Inventors: Yue GUO, Redwood City, CA (US); Yang YANG, San Diego, CA (US); A N M Wasekul AZAD, Santa Clara, CA (US); Kartik RAMASWAMY, San Jose, CA (US)

(21) Appl. No.: 18/494,319

(22) Filed: Oct. 25, 2023

(51) Int. Cl. H01J 37/32; H01L 21/66

(52) U.S. Cl. CPC H01J 37/3299; H01J 37/32183; H01L 22/26; H01J 2237/24564

(57) ABSTRACT

A method of processing a substrate. The method including delivering, by an RF generator, an RF signal to a processing volume of a processing chamber through an RF match including a configurable impedance altering element. Measuring in real-time, an electrical characteristic of the RF signal. Determining in real-time, a target electrical characteristic based upon a comparison between a calibrated electrical characteristic value and the measured electrical characteristic, in which the calibrated electrical characteristic value is selected to achieve at least one desired plasma processing parameter result. Adjusting in real-time, a setting of the configurable impedance altering element of the RF match to achieve the target electrical characteristic and maintaining, the target electrical characteristic by controlling the setting of the configurable impedance altering element of the RF match.

### BACKGROUND

### Field

Embodiments of the present subject matter generally relate to a system and methods used in semiconductor device manufacturing. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

A typical RIE plasma processing chamber includes a radio frequency (RF) generator, which supplies an RF voltage to a power electrode. In a capacitive coupled gas discharge, the plasma is created by using an RF generator that is coupled to the power electrode that is disposed within an electrostatic chuck (ESC) assembly or within another portion of the processing chamber. Typically, an RF matching network (“RF match”) tunes an RF signal provided from the RF generator to deliver RF power to an apparent load of 50Ω to minimize the reflected power and maximize the power delivery efficiency. If an impedance of the load is not properly matched to an impedance of a source (e.g., the RF generator), a portion of the forward delivered RF signal can reflect back in an opposite direction along a same transmission line.

Therefore, there is a need for an apparatus and method for processing a substrate in a plasma processing system that solves the problems described above.

### SUMMARY

Embodiments provided herein generally include apparatus, plasma processing systems and methods for tuning in a radio frequency (RF) plasma processing system for improving substrate processing.

One embodiment includes a method of processing a substrate. The method also includes delivering, by an RF generator, an RF signal to a processing volume of a processing chamber, where the delivering of the RF signal further may include passing the RF signal through an RF match, where the RF match includes at least one configurable impedance altering element; measuring in real-time, by a sensor coupled to a transmission line disposed within the RF match or at an output of the RF match and a distance from an electrode disposed within the processing volume, at least one electrical characteristic of the RF signal; determining in real-time, at least one target electrical characteristic based upon a comparison between a calibrated electrical characteristic value and the measured electrical characteristic of the RF signal, where in the calibrated electrical characteristic value is selected to achieve at least one desired plasma processing parameter result; adjusting in real-time, a setting of the configurable impedance altering element of the RF match to achieve the target electrical characteristic; and maintaining in real-time, the target electrical characteristic by controlling the setting of the configurable impedance altering element of the RF match. Other embodiments of this method include corresponding computer systems, apparatus, and computer programs recorded on one or more computer storage devices, each configured to perform the actions of the methods.

Another embodiment includes a plasma processing system. The plasma processing system also includes a processing chamber; a processing volume disposed within the processing chamber, a radio frequency (RF) generator configured to deliver an RF signal. The system also includes an RF match, where the RF match includes at least one configurable impedance altering element. The system also includes a sensor, where the sensor is coupled to a transmission line disposed within the RF match, or at an output of the RF match and a distance from an electrode disposed within the processing volume. The system also includes at least one controller may include a memory that includes computer-readable instructions stored therein, and the computer-readable instructions, when executed, in real-time, by a processor of the controller, cause: a delivery, by the RF generator, of the RF signal to the processing volume, where the delivery of the RF signal further may include passing the RF signal through the RF match; a measurement in real-time, by the sensor, of at least one electrical characteristic of the RF signal; a determination in real-time, of at least one target electrical characteristic based upon a comparison between a calibrated electrical characteristic value and the measured electrical characteristic of the RF signal, where in the calibrated electrical characteristic value is selected to achieve at least one desired plasma processing parameter result; Other embodiments of this system include corresponding computer systems, apparatus, and computer programs recorded on one or more computer storage devices, each configured to perform the actions of the methods.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic representation of a plasma processing system, in accordance with certain embodiments of the present disclosure.

FIG. 1B is a schematic detailed cross-sectional view of the plasma processing system, in accordance with certain embodiments of the present disclosure.

FIG. 2 shows a voltage waveform that is established on a substrate due to a voltage waveform applied to an electrode of a processing chamber, in accordance with certain embodiments of the present disclosure.

FIG. 3 is a schematic representation of a radio frequency (RF) matching network, in accordance with certain embodiments of the present disclosure.

FIG. 4 is a schematic representation of a plasma processing system with RF generators and respective RF match circuits, in accordance with certain embodiments of the present disclosure.

FIG. 5 is a graph is a schematic representation of a plasma processing system having a sensor coupled to an output of a pulsed voltage (PV) waveform generator, in accordance with certain embodiments of the present disclosure.

FIG. 6A illustrates an example of an equivalent circuit including an impendence matching network, in accordance with certain embodiments of the present disclosure.

FIG. 6B is a graph illustrating an RF impedance, in accordance with certain embodiments of the present disclosure.

FIG. 7 is a process flow diagram illustrating a method for processing a substrate in a plasma processing system, in accordance with certain embodiments of the present disclosure.

FIG. 8A is a graph of ion flux as measured by a calibration substrate as a function of RF power, in accordance with certain embodiments of the present disclosure.

FIG. 8B is a graph of a generated DC bias as measured by a calibration substrate as a function of RF power, in accordance with certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a system used in a semiconductor device manufacturing process. More specifically, embodiments provided herein generally include apparatus and methods for tuning a radio frequency (RF) plasma processing system to provide, modify and/or control the delivery, generation and/or application of real-time measurement and control of a plasma created during plasma processing. For example, an RF matching configuration may be identified to meet certain plasma processing parameters (e.g., improve, or reduce, an etch rate, a process variation, and/or a uniformity), which are sometimes referred to herein as substrate processing metrics. The processing system may be implemented with a sensor that measures electrical characteristics during substrate processing. Based on the measurements, one or more processing components (e.g., one or more match circuits, pulsed voltage (PV) waveform generator, and/or radio frequency (RF) generator) may be controlled in accordance with the identified RF matching configuration. For instance, the configuration may include, in real-time, adding, subtracting, adjusting, or modifying, impedance, admittance, reactance, susceptance, resistance, conductance, filtering, short(s), shunt(s), transmission line characteristics, or other metric, or combination of metrics, associated with one or more RF matching networks that improve plasma processing parameters.

### Plasma Processing System Examples

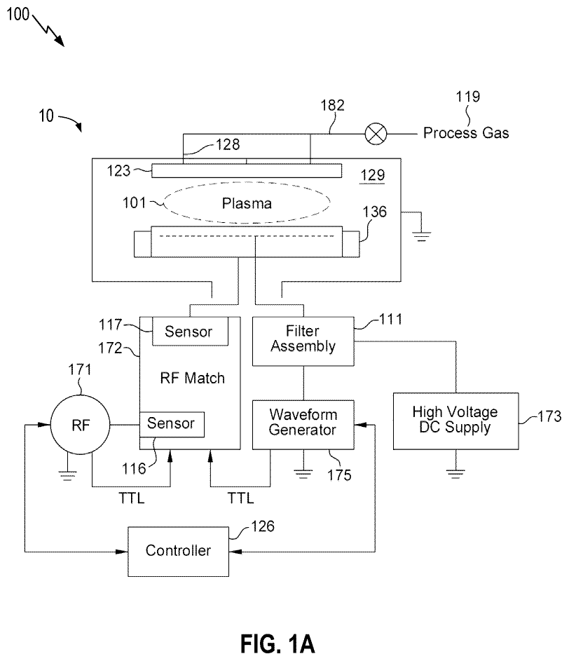

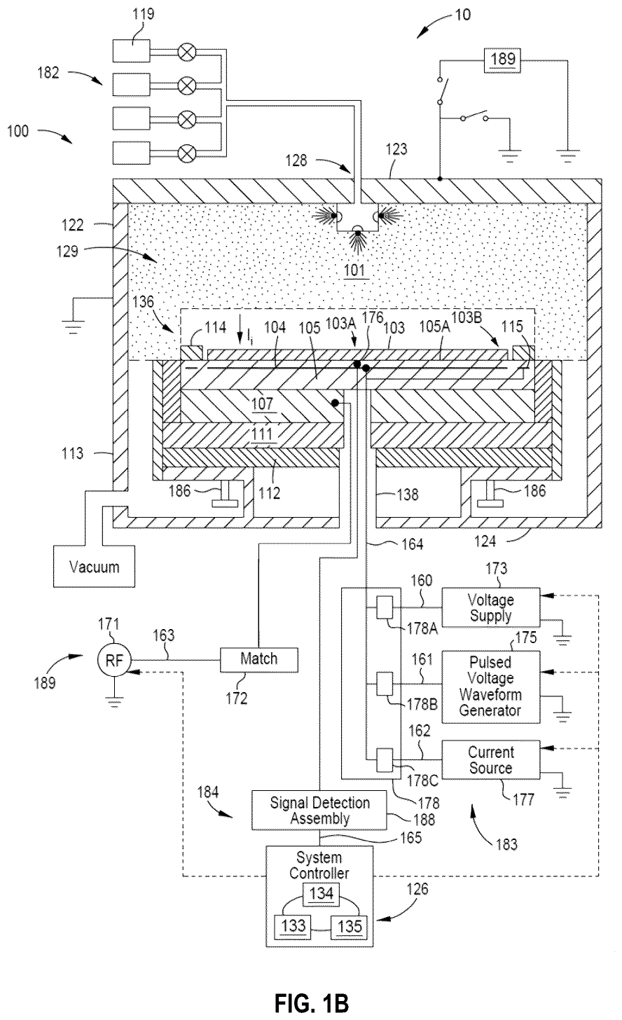

FIG. 1A is a schematic representation of a plasma processing system. The plasma processing system 100 is configured for plasma-assisted etching processes, such as a reactive ion etch (RIE) plasma processing. The plasma processing system 100 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1A, the plasma processing system 100 is configured to form a capacitive coupled plasma (CPP). However, in some embodiments, a plasma may alternately be generated by an inductively coupled source disposed over a processing region of the plasma processing system 100.

The plasma processing system 100 includes a processing chamber 10, a substrate support assembly 136, a gas delivery system 182, a high voltage DC supply 173, a RF generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 by a vacuum delivery system (not shown) of the processing chamber 10 during processing.

The gas delivery system 182, which is coupled to the processing volume 129 of the processing chamber 10 is configured to deliver at least one processing gas from at least one processing gas source 119 to the processing volume 129 of the processing chamber 10. The gas delivery system 182 includes the processing gas source 119 and one or more gas inlets 128 positioned through the chamber lid 123. The gas inlets 128 are configured to deliver one or more processing gasses to the processing volume 129 of the processing chamber 10.

The processing chamber 10 includes an upper electrode (e.g., the chamber lid 123) and a lower electrode (e.g., the substrate support assembly 136) positioned in the processing volume 129 of the processing chamber 10. The upper and lower electrodes face one another. In one embodiment, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode. For example, the RF generator 171 may deliver an RF source power to an RF baseplate within a cathode assembly (e.g., in the substrate support assembly 136) for plasma production, whereas the upper electrode is grounded. A center frequency of the RF source power can be from 13.56 MHz to very high frequency band such as 40 MHz, 60 MHz, 120 MHz or 162 MHz. In some examples, the RF source power can also be delivered through the upper electrode. The RF source power can be operated in a continuous mode or a pulsed mode. A pulsing frequency of the RF power can be from 100 to 10 KHz, and duty cycles are ranging from 5% to 95%. The RF generator 171 has a frequency tuning capability and can adjust its RF power frequency within e.g., ±5% or ±10%. In some embodiments, the RF generator 171 switches the RF power frequency at a predefined speed (e.g., two nanoseconds, fifty nanoseconds, etc.).

The substrate support assembly 136 may be coupled to a high voltage DC supply 173 that supplies a chucking voltage thereto. The high voltage DC supply 173 may be coupled to a filter assembly 178 that is disposed between the high voltage DC supply 173 and the substrate support assembly 136.

The filter assembly 178 is configured to electronically isolate the high voltage DC supply 173 during plasma processing. In one configuration, a static DV voltage is between about −5000V and about 5000V, and is delivered using an electrical conductor (such as a coaxial power delivery line). The filter assembly 178 may include multiple filtering components or a single common filter.

The substrate support assembly 136 is coupled to a pulsed voltage (PV) waveform generator 175 configured to supply a PV to bias the substrate support assembly 136. The PV waveform generator 175 is coupled to the filter assembly 178. The filter assembly 178 is disposed between the PV waveform generator 175 and the substrate support assembly 136. The filter assembly 178 is configured to electronically isolate the PV waveform generator 175 during plasma processing.

The substrate support assembly 136 is coupled to the RF generator 171 configured to deliver an RF signal to the processing volume 129 of the processing chamber 10. The RF generator 171 is electronically coupled to the RF match 172 disposed between the RF generator 171 and the processing volume 129 of the processing chamber 10. For example, the RF match 172 is an electrical circuit used between the RF generator 171 and a plasma reactor (e.g., the processing volume 129 of the processing chamber 10) to optimize power delivery efficiency. One or more RF filters (e.g., within the RF match 172) are designed to only allow powers in a selected frequency range, and to isolate RF power supplies from each other. In some cases, a bandwidth of an RF filter has to be larger than a frequency tuning range of the RF generator 171.

During the plasma processing, the RF generator 171 delivers an RF signal to the substrate support assembly 136 via the RF match 172. For example, the RF signal is applied to a load (e.g., gas) in the processing volume 129 of the processing chamber 10. If an impedance of the load is not properly matched to an impedance of a source (e.g., the RF generator 171), a portion of a waveform can reflect back in an opposite direction. Accordingly, to prevent a substantial portion of the waveform from reflecting back, some implementations find a match impedance (e.g., a matching point) by adjusting one or more components of the RF match 172 as the source and load impedances change.

The RF match 172 is electrically coupled to the RF generator 171, the substrate support assembly 136, and the PV waveform generator 175. The RF match 172 is configured to receive a synchronization signal from either or both of the RF generator 171 and the PV waveform generator 175.

The RF generator 171 and the PV waveform generator 175 are each directly coupled to a system controller 126. The system controller 126 synchronizes the respective generated RF signal and PV waveform.

Sensors can be placed at an input and/or output of the RF match 172 to measure impedance and other parameters. These sensors can be synchronized using an external transistor-transistor logic (TTL) synchronization signal from an advanced waveform generator and/or RF generators or using measured values to determine timing internally. For example, an output sensor 117 is configured to measure the electrical characteristics of the processing chamber 10, and other characteristics such as the voltage, current, harmonics, phase, spectral components, and/or the like. An input sensor 116 is configured to measure the impedance of the RF generator 171 and other characteristics such as the voltage, current, harmonics, phase, reflected power, spectral component, or similar. Based on either of the synchronization signals or the measured values of the processing chamber 10, the RF match 172 is able to capture fast impedance changes and optimize impedance matching.

The PV waveform generator 175 is used to supply a PV waveform and/or a tailored voltage waveform, which is a sum of harmonic frequencies associated with the waveform. The PV waveform generator 175 may output a synchronization TTL signal to the RF match 172. The voltage waveform is coupled to a bias electrode (e.g., a bias electrode 104 shown in FIG. 1B) through the filter assembly 178. The high voltage DC supply 173 is applied to chuck a substrate during a process for a thermal control. In some cases, there can be a third electrode at an edge of the cathode assembly for edge uniformity control.

FIG. 1B is a schematic detailed cross-sectional view of the plasma processing system 100. As shown in FIG. 1B, the plasma processing system 100 is configured to form a capacitively coupled plasma (CCP). However, in some embodiments, the plasma 101 may alternately be generated by an inductively coupled source disposed over the processing region of the plasma processing system 100. In this configuration, a coil may be placed on top of a ceramic lid (e.g., vacuum boundary) of the processing chamber 10.

The plasma processing system 100 includes the processing chamber 10, the substrate support assembly 136, the gas delivery system 182, a DC power system 183, an RF power system 189, and the system controller 126. The processing chamber 10 includes a chamber body 113 that includes the chamber lid 123, one or more sidewalls 122, and a chamber base 124. The chamber lid 123, the one or more sidewalls 122, and the chamber base 124 collectively define the processing volume 129 of the processing chamber 10. The one or more sidewalls 122 and the chamber base 124 include materials (such as aluminum, aluminum alloys, or stainless steel alloys) that are sized and shaped to form a structural support for elements of the processing chamber 10 and are configured to withstand the pressures and added energy applied to them while the plasma 101 is generated within a vacuum environment maintained in the processing volume 129 of the processing chamber 10 during processing. A substrate 103 is loaded into, and removed from, the processing volume 129 of the processing chamber 10 through an opening (not shown) in one of the sidewalls 122. The opening is sealed with a slit valve (not shown) during plasma processing of the substrate 103.

The gas delivery system 182, which is coupled to the processing volume 129 of the processing chamber 10, includes the processing gas source 119 and the gas inlet 128 disposed through the chamber lid 123. The gas inlet 128 is configured to deliver one or more processing gases to the processing volume 129 of the processing chamber 10 from the processing gas source 119.

As noted above, the processing chamber 10 includes the upper electrode (e.g., the chamber lid 123) and the lower electrode (e.g., the substrate support assembly 136) disposed in the processing volume 129 of the processing chamber 10. The upper electrode and lower electrode are positioned to face each other. As seen in FIG. 1B, the RF generator 171 is electrically coupled to the lower electrode. The RF generator 171 is configured to deliver an RF signal to ignite and maintain the plasma 101 between the upper and lower electrodes. In some alternative configurations, the RF generator 171 can also be electrically coupled to the upper electrode.

The substrate support assembly 136 includes a substrate support 105, a substrate support base 107, an insulator plate 111, a ground plate 112, a plurality of lift pins 186, one or more substrate potential sensing assemblies 184 (e.g., including a signal detecting assembly 188), and a bias electrode 104. Each of the lift pins 186 are disposed through a through hole 185 formed in the substrate support assembly 136 and are used to facilitate the transfer of the substrate 103 to and from a substrate receiving surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. The substrate support base 107 is configured to regulate the temperature of both the substrate support 105, and the substrate 103 disposed on the substrate support 105 during substrate processing. The substrate support base 107 includes one or more cooling channels (not shown) disposed therein that are fluidly coupled to, and in fluid communication with, a coolant source (not shown), such as a refrigerant source or substrate source having a relatively high electrical resistance. The substrate support 105 includes a heater (not shown) to heat the substrate support 105 and the substrate 103 disposed on the substrate support 105.

The bias electrode 104 is embedded in a dielectric material of the substrate support 105. The bias electrode 104 is formed of one or more electrically conductive parts. The electrically conductive parts include meshes, foils, plates, or combinations thereof. The bias electrode 104 functions as a chucking pole (i.e., electrostatic chucking electrode) that is used to secure (e.g., electrostatically chuck) the substrate 103 to the substrate receiving surface 105A of the substrate support 105. A parallel plate like structure is formed by the bias electrode 104 and a layer of the dielectric material that is disposed between the bias electrode 104 and the substrate receiving surface 105A. The dielectric material can have an effective capacitance CE of between about 5 nF and about 50 nF. A layer of the dielectric material (e.g., aluminum nitride (AlN), aluminum oxide (Al₂O₃), etc.) has a thickness between about 0.3 mm and about 5 mm, such as between about 0.1 mm and about 3 mm, such as between about 0.1 mm and about 1 mm, or even between about 0.1 mm and 0.5 mm. The bias electrode 104 is electrically coupled to a clamping network, which provides a chucking voltage thereto. The clamping network includes the High voltage DC supply 173 (e.g., a high voltage DC supply) that is coupled to a filter 178A of the filter assembly 178 that is disposed between the High voltage DC supply 173 and the bias electrode 104. The filter 178A is a low-pass filter that is configured to block RF frequency and PV waveform signals provided by other biasing components found within the processing chamber 10 from reaching the High voltage DC supply 173 during the plasma processing. The static DV voltage is between about −5000V and about 5000V, and is delivered using an electrical conductor (such as a coaxial power delivery line 106). The bias electrode 104 may bias the substrate 103 with the respect to the plasma 101 using one or more of the PV biasing schemes.

The substrate support assembly 136 includes an edge control electrode 115. The edge control electrode 115 is formed of one or more electrically conductive parts. The electrically conductive parts include meshes, foils, plates, or combinations thereof. The edge control electrode 115 is positioned below an edge ring 114 and surrounds the bias electrode 104 and/or is disposed a distance from a center of the bias electrode 104. For the processing chamber 10 that is configured to process circular substrates, the edge control electrode 115 is annular in shape, is made from a conductive material, and is configured to surround at least a portion of the bias electrode 104. As seen in FIG. 1B, the edge control electrode 115 is positioned within a region of the substrate support 105, and is biased by use of the PV waveform generator 175. The edge control electrode 115 is biased by use of a PV waveform generator that is different from the PV waveform generator 175 used for the bias electrode 104. The edge control electrode 115 is biased by splitting part of a signal provided from the PV waveform generator 175 to the bias electrode 104.

The DC power system 183 includes the High voltage DC supply 173, the PV waveform generator 175, and a current source 177. The RF power system 189 includes the RF generator 171, and the RF matching 172. As shown in FIG. 1B, a power delivery line 163 electrically connects an output of the RF generator 171 to the RF match 172, and the substrate support base 107. As noted above, during the plasma processing, the High voltage DC supply 173 provides a constant chucking voltage, while the RF generator 171 delivers the RF signal to the processing region, and the PV waveform generator 175 establishes the PV waveform at the bias electrode 104. For example, a sufficient amount of the RF power is applied to an RF bias voltage signal (which is also referred to herein as the RF signal), and the RF signal is provided to an electrode (e.g., the substrate support base 107) to cause the plasma 101 to be formed in the processing volume 129 of the processing chamber 10. The RF signal has a frequency range between about 1 MHz and about 200 MHz, such as between 2 MHz and 40 MHz.

The DC power system 183 includes the filter assembly 178 to electrically isolate one or more of the components contained within the DC power system 183. A power delivery line 160 electrically connects an output of the High voltage DC supply 173 to the filter assembly 178. A power delivery line 161 electrically connects the output of the PV waveform generator 175 to the filter assembly 178. A power delivery line 162 connects the output of the current source 177 to the filter assembly 178.

The current source 177 is selectively coupled to the bias electrode 104 by use of a switch (not shown) disposed in the power delivery line 162, to allow the current source 177 to deliver a desired current to the bias electrode 104 during one or more stages (e.g., ion current stage) of the voltage waveform generated by the PV waveform generator 175.

The filter assembly 178 includes multiple separate filtering components (i.e., discrete filters 178A-178C) that are each electrically coupled to an output node via a power delivery line 164. The filter assembly 178 may include one common filter electrically coupled to the output node via the power delivery line 164. The power delivery lines 160-164 include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

The system controller 126, also referred to herein as a processing chamber controller, includes a central processing unit (CPU) 133, a memory 134, and support circuits 135. The system controller 126 is used to control a process sequence used to process the substrate 103. One or more system controllers 126 may be used with one or any combination of the various systems described herein to perform, in real-time, the methods described herein.

The CPU is a computer processor configured for use in an industrial setting for controlling the processing chamber and sub-processors related thereto. The memory 134 described herein, which is generally non-volatile memory, can include random access memory, read-inly memory, hard disk drive, or other suitable forms of digital storage, local or remote. The support circuits 135 are coupled to the CPU 133 and include cache, clock circuits, input/output subsystems, power supplied, and the like, and combinations thereof. Software instructions (program) and data can be coded and stored within the memory 134 for instructing a processor within the CPU 133. A software program (or computer instructions) readable by the CPU 133 in the system controller 126 determines which tasks are performable by the components in the plasma processing system 100.

The program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 100 to perform the various process tasks and various process sequences used to implement the methods described herein. The program includes instructions that are used to perform one or more of the operations described herein.

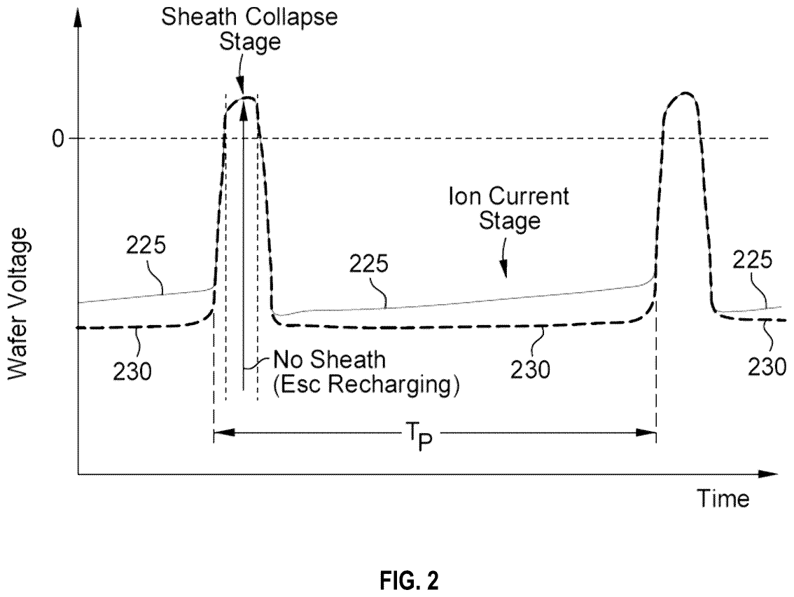

FIG. 2 illustrates two separate voltage waveforms established at the substrate 103 disposed on the substrate receiving surface 105A of the substrate support assembly 136 of the processing chamber 10 due to the delivery of PV waveforms to the bias electrode 104 of the processing chamber 10. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the bias electrode 104 of the processing chamber 10 during an “ion current stage” portion of the PV waveform cycle by use of the current source 177. The compensated PV waveform can alternatively be established by applying a negative voltage ramp during the ion current stage of the PV waveform generated by the PV waveform generator 175. The PV waveform cycle of the waveforms 225, 230 each have a period Tp, which is, for example, typically between 2 microsecond (μs) and 10 μs, such as 2.5 μs. The ion current stage of the PV waveform cycle will typically take up between about 50% and about 95% of the period Tp, such as from about 80% to about 90% of the period Tp.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. At a beginning of the ion current stage, a drop in the voltage at the substrate 103 is created, due to the delivery of a negative portion of the PV waveform (e.g., the ion current portion) provided to the bias electrode 104 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. In some embodiments, it is desirable for the ion current stage to include a region of the PV waveform that achieves the voltage at the substrate 103 that is stable or minimally varying throughout the stage, as illustrated in FIG. 2 by the waveform 230. One will note that significant variations in the voltage established at the substrate 103 during the ion current stage, such as shown by the positive slope in the waveform 225, will undesirably cause a variation in the ion energy distribution (IED) and thus cause undesirable characteristics of the etched features to be formed in the substrate 103 during the RIE process.

Plasma sheath impedance varies with supplied PV waveform voltages. The RF match 172 can use either or both of the synchronization signals and/or use its internal sensors to sample impedances in different processing phases. In one example, a synchronization signal or electrical characteristics determined by the input sensor 116 or the output sensor 117 are used to trigger the RF match 172 to determine at least two different impendences at different processing stages. Then, the RF match 172 updates its matching point based on the at least two different impedances.

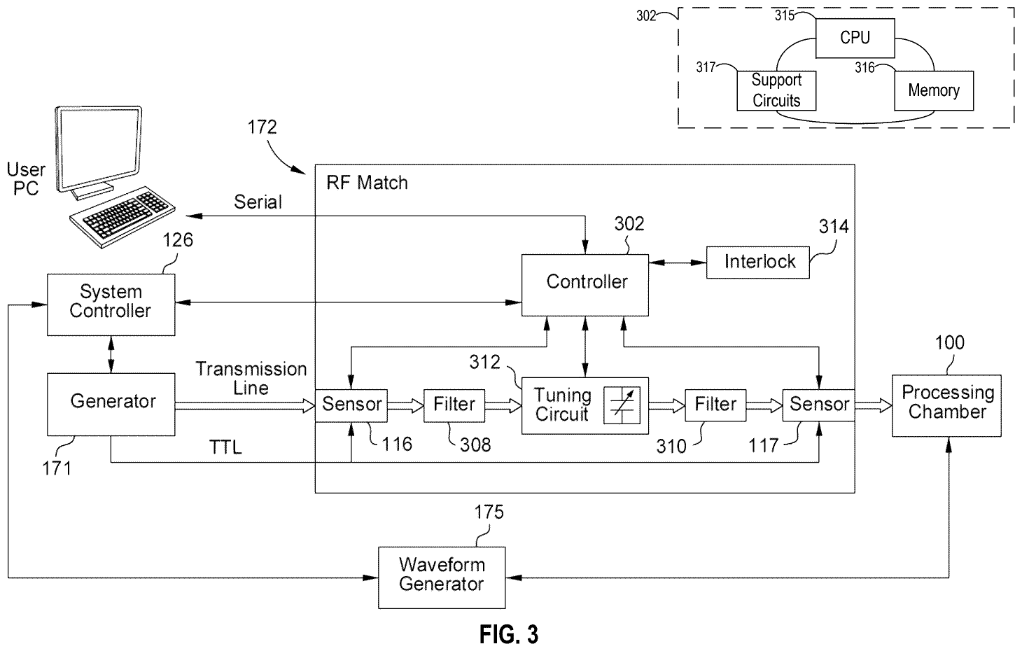

FIG. 3 is a schematic representation of an RF match 172. The RF match 172 includes a controller 302, the input sensor 116, the output sensor 117, a first RF filter 308, a second RF filter 310, a tuning circuit 312, an interlock 314, and a memory 316. The two RF filter circuits (e.g., the first RF filter 308 and the second RF filter 310) are near both an input and an output of the RF match 172. In some cases, only one RF filter may be used near the output of the RF match 172.

The RF match 172 is connected to the RF generator 171 through a 50Ω transmission line. The RF generator 171 may supply power at frequencies between 100 KHz and 200 MHz. The RF generator 171 has a frequency tuning capability and can adjust its RF power frequency within e.g. ±5% or ±10%. The RF generator 171 sends a TTL signal to the input sensor 116 and the output sensor 117 directly for fast response and better synchronization. The RF match 172 may be configured to receive the RF signal from the RF generator 171, tune the RF signal to minimize the reflected power and maximize power delivery efficiency, and deliver the tuned RF signal to the processing chamber 10, in some implementations. Simultaneously, as noted above, the PV waveform generator 175 is configured to provide the PV waveform to the processing chamber 10. The RF generator 171 and the PV waveform generator 175 are both coupled to and synchronized by the controller 302.

The controller 302 may work with various communication protocols, e.g., RS-232, RS-485, USB, Ethernet, or Ethernet for Control Automation Technology (ECAT). The controller 302 may serve as a local EtherCAT master. Other components (e.g., the input sensor 116, the output sensor 117, motors) are EtherCAT slave devices, which are controlled by the controller 302.

The controller 302 may be coupled to the interlock 314, the memory 316, the tuning circuit 312, the input sensor 116, the output sensor 117, support circuits 317, and the system controller 126. The controller 302 includes a CPU 315, memory 316, and support circuits 317. One or more controllers 302 may be used with one or any combination of the various systems described herein. The controller 302 is configured to control the tuning circuit 312 to change an impedance parameter of the RF match 172. In one example, the tuning circuit 312 is a T-network tuning circuit. In another example, the tuning circuit 312 is a pi-network tuning circuit. In another example, the tuning circuit 312 is an L-network tuning circuit. The tuning circuit 312 may include one or more configurable impedance altering elements (e.g., capacitors and/or variable capacitors) and inductive elements (e.g., inductors) that can be adjusted (e.g., a capacitive value, or an inductive value) by the controller 302 to change the impedance of the RF signal delivered to the processing chamber 10.

The CPU 315 is a computer processor configured for use in an industrial setting for controlling the processing chamber and sub-processors related thereto. The memory 316 described herein, which is generally non-volatile memory, can include random access memory, read-inly memory, hard disk drive, or other suitable forms of digital storage, local or remote. The support circuits 317 are coupled to the CPU 315 and include cache, clock circuits, input/output subsystems, power supplied, and the like, and combinations thereof. Software instructions (program) and data can be coded and stored within the memory 316 for instructing a processor within the CPU 315. A software program (or computer instructions) readable by the CPU 315 in the controller 302 determines which tasks are performable by the components of the RF Match 172.

The memory 316 may be programmed for long term or short term memory storage. The memory 316 described herein, which is generally non-volatile memory, can include random access memory, read-only memory, hard disk drive, or other suitable forms of digital storage, local or remote. Software instructions (program) and data can be coded and stored within the memory 316 for instructing a processor within the controller 302. A software program (or computer instructions) readable by controller 302 determines which tasks are performable by the components in the plasma processing system 100. The program, which is readable by the controller 302 includes code, which, when executed, performs tasks relating to the plasma processing schemes described herein. The program may include instructions that are used to control the RF match 172 using the methods described herein. The program includes instructions that are used to perform one or more of the operations described herein.

The interlock 314 is implemented for safety purposes to control over temperature switches, cable-in-place switches, and match-in-place switches, etc. The interlock 314 is open when failure happens, and an interlock signal will be sent from a local microcontroller to both a user laptop and the system controller 126 to shut the system off.

The system controller 126 can communicate with the RF match 172, the RF generator 171 and/or other chamber components. The controller 302 can communicate with the system controller 126 using EtherCAT. The controller 302 can do a master to slave conversion, which allows communication to the system controller 126 EtherCAT master. The controller 302 receives requests from the system controller 126, and provides feedback. Also, the system controller 126 receives forward and reflected power information from the RF generator 171 and gets data from all internal devices of the RF match 172. The RF generator 171 can also be controlled by the system controller 126 for a cooperative intelligent real time control and tuning.

The RF match 172 may include a serial control port for algorithm uploading, and an external match control (e.g., by using an external software and application programming interface (API)). Automatic impedance tuning algorithms and preset configurable impedance altering element positions are stored on the memory 316. Sensor data and tuning algorithms can be accessed from an external user laptop, which provides great flexibility to the RF match 172. Furthermore, advanced process related control algorithm can be deployed in real time. The RF match 172 can operate fully autonomously, cooperatively with the system controller 126 or manually controlled by the external user laptop.

The output sensor 117 may include a voltage sensor and/or a current sensor configured to measure the fundamentals and selected harmonics of the plasma processing system 100 explained above. The input sensor 116 may include a voltage sensor and/or a current sensor configured to measure characteristics of the RF signal such as voltage, current, phase, harmonics, reflected power, spectral component, or similar. In some cases, only one sensor can be used at the input of the RF match 172. Sensor readings can be used in a feedback and feedforward algorithms for impedance matching.

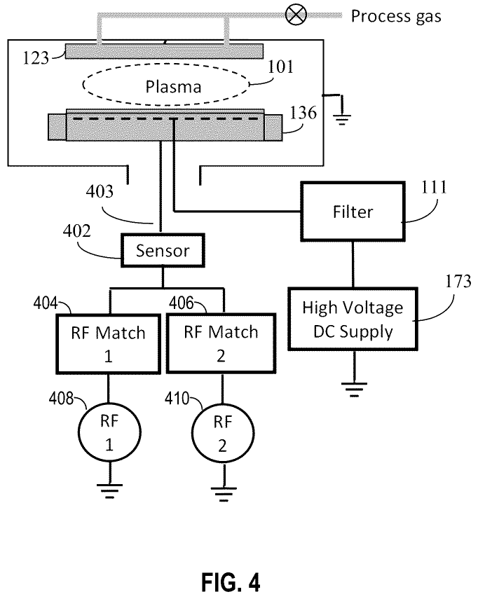

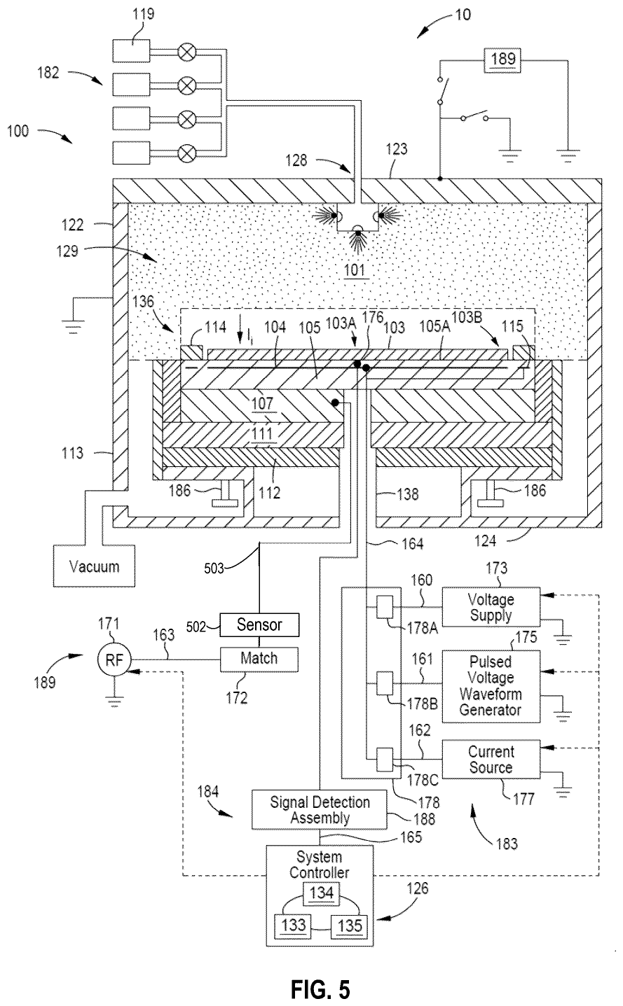

The output sensor 117 is configured to sample voltage and/or current provided on a transmission line connected to the RF match 172 within the plasma processing system 100 over a first period of time and report them to the controller 302. In some examples, the output sensor 117 is coupled to a transmission line 403, 503 (e.g., FIGS. 4 and 5) that is coupled to an electrode disposed within the substrate support assembly 136, which is discussed further below. The output sensor 117 is also configured to sample a second set of impedances of the plasma processing system 100 over a second period of time and report them to the controller 302. The first period of time may begin after a first delay that is triggered (i.e. measured) after a first portion of a waveform pulse of a synchronization signal or internally by the sensors detecting a change in a characteristic of the PV waveform or the RF signal. The second period of time may begin after a second delay that is triggered at the same time as the first delay. The second delay is longer than the first delay.

The controller 302 uses the both sets of impedances to determine a first impedance and a second impedance and combine them into a combined impedance. Then, based on the combined impedance parameter, the controller 302 adjusts the one or more configurable impedance altering elements of the tuning circuit 312 to change the matching point of the RF match 172 so that the impedance of the generated RF signal matches the impedance of the plasma processing system 100. Then, after adjusting the tuning circuit 312 based on the combined impedance parameter, the controller 302 may further fine tune the tuning circuit 312 based on the impedance of the RF signal sampled by the input sensor 116.

### Example Techniques for Substrate Processing and Tuning

As described with respect to FIG. 3, some implementations use an RF match to reduce (e.g., minimize) reflected power at a designed frequency. The input and output sensors (e.g., if available), such as input sensor 116, and output sensor 117, may be calibrated to measure characteristics of the RF signal such as voltage, current, phase, or harmonics, and may operate to modify reflected power. Certain embodiments of the present disclosure are directed towards processing system with one or more sensors measuring not only fundamental frequencies but also harmonics and the intermodulation products to be used tune and improve various processing metrics.

While reducing reflected power for the RF generator may be considered, some embodiments of the present disclosure consider other criteria for tuning during substrate processing. For example, certain embodiments provide a tuning algorithms that may be developed using a combination of at least two of fundamental, harmonic, and intermodulation frequencies for improved substrate results and more precise process control. As used herein, substrate results (also referred to as a “wafer processing metric”) may refer to one or more quality parameters associated with processing a substrate, such as a level of process variation, etch rate, and/or uniformity.

In some embodiments, RF match tuning may be performed in real-time using voltage, current, phase, or adding, subtracting, or tuning, impedance, admittance, reactance, susceptance, resistance, conductance, filtering, short(s), shunt(s), transmission line characteristics, other metric, or any combination of metrics. The RF match may tune to configurations which are related to plasma processing parameters such as less process variation, faster etch rate, better etch uniformity (or deposition uniformity), or similar parameter. In some embodiments of the present disclosure, plasma processing parameters, such as ion density, neutral density, ion flux, temperature, electromagnetic field densities, and other plasma processing parameters, may be reconstructed from the measurements, and reported to a controller for real time graphing and to be used for, in real-time, adding, subtracting, or tuning, impedance, admittance, reactance, susceptance, resistance, conductance, filtering, short(s), shunt(s), transmission line characteristics, other metric, or any combination of metrics, associated with one or more RF matching networks, as described in more detail herein.

FIG. 4 is a schematic representation of a plasma processing system with two RF generators 408, 410 (labeled “RF1” and “RF2”) and RF match 404 (labeled “RF match 1”) and RF match 406 (labeled “RF match 2”). Each of the RF generators 408, 410 may be implemented in a similar manner as RF generator 171 described with respect to FIG. 1. Each of the RF match 404 and RF match 406 may be implemented in a similar manner as RF match 172 described herein. As shown, a sensor 402 may be coupled to the output of RF match 404 and the output of RF match 406 in FIG. 4. Thus, sensor 402 may be used to measure electrical characteristics, for example the voltage and current waveforms, of the combined output of the RF match 404 and RF match 406.

The RF generators 408, 410 may generate two or more frequencies which may be synchronized with phase control. In some cases, the RF generators may be operated in-phase or out-of-phase, at differing magnitudes, depending on calibration to meet certain processing metrics. For example, the plasma processing parameters may be the ion flux, or DC voltage, or both, at the substrate. In some embodiments, another RF signal may be applied from the top electrode (e.g., the chamber lid 123) in capacitively coupled plasma reactors or a top coil in inductively coupled plasma reactors. In some embodiments, the top electrode (e.g., the chamber lid 123 may be grounded. As shown, the sensor 402 may be at the RF match output for measuring electrical characteristics, for example voltage and current. In some embodiments the sensor may be coupled to an RF rod that is used to couple the RF generators 408, 410 to an electrode (e.g., bias electrode 104 in FIG. 1B) disposed with the substrate support assembly 136 within the processing region of the processing chamber. While not shown in FIG. 4, in some embodiments, an RF filter may be positioned between the output of each of the RF matches 404, 406 and the sensor 402 to prevent an RF signal provided by one of the RF generators 408, 410 from causing damage to the other RF match 404, 406 and associate RF generator 408, 410.

FIG. 5 is a schematic representation of the plasma processing system of FIG. 1B that further includes a sensor 502 coupled to the RF match 172 output, in accordance with certain embodiments of the present disclosure. In other embodiments, the sensor 502, may be coupled to the transmission line at any point prior to the substrate support base 107. In yet other embodiments, sensor 502 is the output sensor 117 within the RF Match 172. The sensor 502 measures, in real-time, the electrical characteristics of the RF signal such as voltage, current, phase, harmonics, reflected power, spectral component, or similar from RF Match 172, based on which the RF match 172 is controlled. The measured electrical characteristics may be reported to the system controller 126, or controller 302, or both the system controller 126 and controller 302 for real time control of the RF Match 172 and/or RF generator 171.

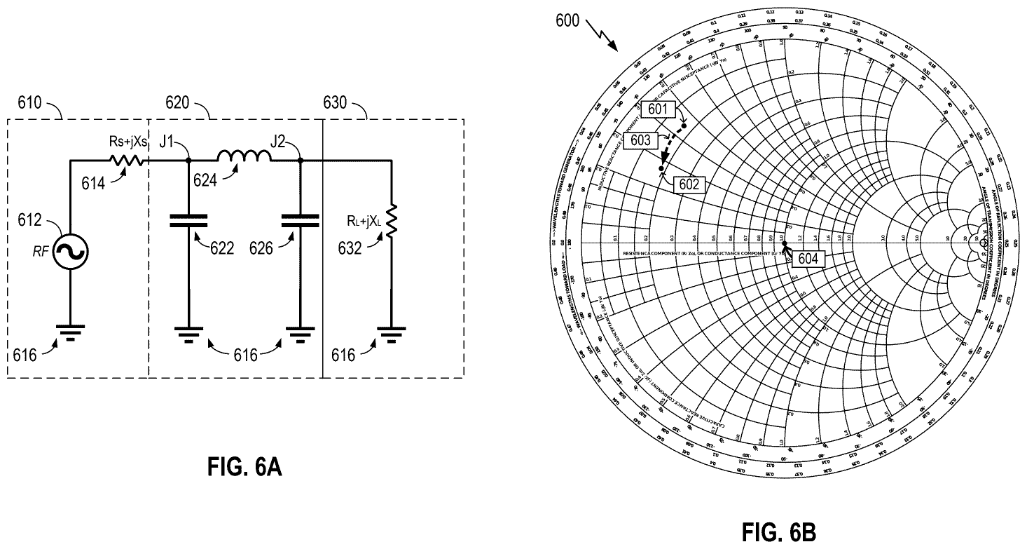

FIG. 6A illustrates an example circuit including an impendence matching network. The equivalent circuit can be divided into three areas, the source 610, the impedance matching network 620, and the load 630. In this embodiment, the impedance matching network is representative model of a pi-type impedance matching network. In other embodiments, an L-type, T-type, stub, transformer, quarter-wave transformer, lumped element, filter, or other type of impedance matching implementation may be employed.

The source 610 includes a RF source 612 having an input and an output, a source resistance/reactance 614 having an input and an output, and a common ground 616 having a ground connection. The source 610 may be representative of RF generator 171.

The input of RF source 612 is electrically coupled to the ground connection of the common ground 616. The output of RF source 612 is electrically coupled to the input of source resistance/reactance 654. The output of the source resistance/reactance 614 is electrically coupled to a junction J1 within the impedance matching network 620.

The RF source 612, and the source resistance/reactance 614, combine to form a source impedance Z_{S}, where Z_{S}=R_{S}±jX_{S}, where R_{S} represents the resistive component of source 610 and jX_{S} represents the reactive component of source 610.

The impedance matching network 620 includes the junction J1, a junction J2, a first capacitor 622 having an input and an output, an inductor 624 having an input and an output, a second capacitor 626 having an input and an output, and the common ground 616 having a ground connection. The impedance matching network 620 may be representative of the RF Match 172, or the tuning circuit 312 within the RF Match 172.

The input of the first capacitor 622 is electrically coupled to junction J1. The output of the first capacitor 622 is electrically coupled to the ground connection of the common ground 616. The input of the inductor 624 is electrically coupled to junction J1. The output of the inductor 624 is electrically coupled to junction J2. The input of the second capacitor 626 is electrically coupled to junction J2. The output of the second capacitor 626 is electrically coupled to the ground connection of the common ground 616.

The load includes a load resistance/reactance 632 having an input and an output, and a common ground 616 having a ground connection. The input of the load resistance/reactance 632 is electrically coupled to junction J2 within the impedance matching network 620. The output of the load resistance/reactance 632 is electrically coupled to the ground connection of the common ground 616. The plasma 101 may be representative of the load 630.

The RF source 612, and the source resistance/reactance 614, combine to form a source impedance Z_{S}, where Z_{S}=R_{S}+jX_{S}, where R_{S} represents the resistive component of source 610 and jX_{S} represents the reactive component of source 610.

The load resistance/reactance 632 forms a load impedance Z_{L}, where Z_{L}=R_{L}±jX_{L}, where R_{L} represents the resistive component of the load 630 and jX_{L} represents the reactive component of the load 630.

The traditional purpose of an impedance matching network 620 is to transform the impedance seen at the input of a circuit (e.g., a source impedance Z_{S}) to match the impedance at the output (e.g., a load impedance Z_{L}) to ensure a maximum power transfer between the source 610 and the load 630.

By altering the values of the first capacitor 622, inductor 624, the second capacitor 626, or combination of the configurable impedance altering elements of the impedance matching network 620, an impedance match may be attained between the source 610 and the load 630.

FIG. 6B illustrates a Smith chart 600 in accordance with certain embodiments of the present disclosure. Smith chart 600 is a mathematical transformation of the two-dimensional Cartesian complex plane employed to assist with visualizing and solving problems with impedance matching, such as determining the component values of the impedance matching network 620. Smith chart 600 illustrates the transformation:

$$Γ = \frac{Z - {Z}_{0}}{Z + {Z}_{0}} = \frac{z - 1}{z + 1} ,$$

where

$$z = \frac{Z}{{Z}_{0}} ,$$

i.e., the complex impedance Z, normalized by a reference impedance, Z₀, and where Γ is the signal reflection coefficient. The signal reflection coefficient Γ may be understood as a ratio of the reflected power, from the load 630 back toward the source 610, to that of the initial incident power supplied by the source 610 toward the load 630.

Traditionally, an impedance value of a formed plasma 101 may be identified during calibration to set the tuning circuit 312 of RF Match 172 to reduce the effects of capacitive reactance/susceptance and inductive reactance/susceptance, to operate at the maximum power transfer point 604 in FIG. 6B. For example, by using the tuning circuit 312 of RF Match 172. The maximum power transfer point 604 occurs when the Z=1, indicating that the signal reflection coefficient, Γ=0 and reflected power is at its minimum. By operating at the maximum power transfer point 604, the power delivered by the RF generator 171 is not reflected by the load (e.g., the plasma 101) back toward the RF generator 171. Reflected power can damage the RF generator 171.

In accordance with certain embodiments of the present disclosure, the sensor 502, which is located outside of the processing volume, may measure the electrical characteristics of the RF Signal in real-time. The real-time measured electrical characteristics can then be transformed to an electrode within the electrostatic chuck (ESC) assembly and substrate (or wafer) surface using a two-port network transformation using a Z-parameter transmission matrix to solve for an impedance (Z).

$$[ \begin{matrix}{V}_{1} \\ {V}_{2}\end{matrix} ] = [ \begin{matrix}{Z}_{11} & {Z}_{12} \\ {Z}_{21} & {Z}_{22}\end{matrix} ] [ \begin{matrix}{I}_{1} \\ {I}_{2}\end{matrix} ]$$

For example, the two-port network transformation may determine the measured plasma impedance 601 shown in FIG. 6B. In other embodiments, real-time measured electrical characteristics may be transformed to an electrode within the electrostatic chuck (ESC) assembly and thus substrate surface using a two-port network transformation using admittance (Y), scattering(S), or scattering transfer (T), parameter matrices.

Based upon the results of the transformation, the measured plasma impedance 601 is then used to determine a target plasma impedance 602. In certain embodiments, the target plasma impedance 602 is not the maximum power transfer point 604. Instead, the target plasma impedance 602 is determined to meet a plasma processing parameter, or parameters. The target plasma impedance 602, by not being located at the maximum power transfer point 604, may increase reflected power, and may increase the risk of damaging the source (e.g., RF generator 171).

For example, the target plasma impedance 602 may be determined to provide for etch rate control where the plasma processing parameter is an increased, or reduced, etch rate. In another example, the target plasma impedance 602 may be determined to provide for ion flux control where the plasma processing parameter is an increased, or reduced, ion flux. In another example, the target plasma impedance 602 may be determined to provide for heat flux control where the plasma processing parameter is an increased, or reduced, heat flux. In another example, the target plasma impedance 602 may be determined to provide for etch uniformity control where the plasma processing parameter is an improved, or reduced, etch uniformity. In another example, the target plasma impedance 602 may be determined to provide for power transfer control where the plasma processing parameter is an improved, or reduced, power transfer level.

Once a target plasma impedance 602 is determined, the impedance match tuning (e.g., capacitances, impedances, and/or other configurable impedance altering elements of the impedance matching network 620) are then adjusted (illustrated by arrow 603) to achieve, or approximately achieve, the target plasma impedance 602. Based upon continuing real-time measurement of the RF signal electrical characteristics (e.g., measured plasma impedance 601), the target plasma impedance 602 is continually adjusted, and then maintained, to reduce the difference between the measured plasma impedance 601 and the target plasma impedance 602.

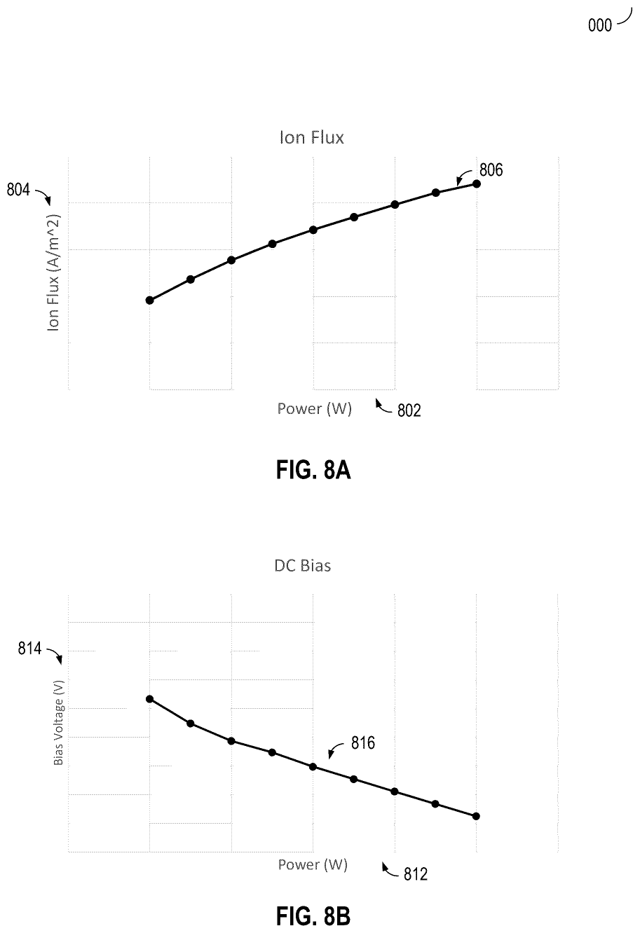

In other embodiments, measurements from the sensor 502 may be used to non-intrusively measure ion flux, or other plasma properties, in real-time providing information that may be used to monitor chamber health and facilitate real-time advanced process control for pressure adjustments, chemistry adjustments, and/or adjustments of RF generator 171. For example, adjust the tuning circuit 312 to an impedance which corresponds to a higher ion flux to increase the etching rate. In some embodiments, a plasma processing parameter, such as ion flux or DC bias can be measured in the plasma processing chamber (e.g., process chamber 10) by use of a calibration substrate that is positioned on a substrate support and is configured to detect the ion flux or DC bias by use of one or more probe/sensor structures attached to one or more regions of the substrate. An example of results measured in a plasma processing chamber is illustrated in FIGS. 8A and 8B.

FIG. 8A provides a graph of an example of ion flux as a function of RF power as measured on a calibration substrate positioned on a substrate support of a plasma processing chamber. FIG. 8A includes a horizontal axis 802 indicating an increase in power in Watts (W) from left to right. FIG. 8A also includes a vertical axis 804 indicating an increase in ion flux, shown in Amperes per meter squared (A/m²). The data plot 806 illustrates the correlation between power and ion flux, showing that as power increases, ion flux also increases. The ion flux as a function of RF power curve can be used by the controller to adjust a plasma processing parameter to achieve a desired process result on a substrate.

FIG. 8B is a graph of an example of a generated DC bias as a function of RF power as measured by a calibration substrate positioned on the substrate support of the plasma processing chamber, in accordance with certain embodiments of the present disclosure. FIG. 8B includes a horizontal axis 812 indicating an increase in power in Watts (W) from left to right. FIG. 8B also includes a vertical axis 814 indicating an increase in negative bias voltage (V) from the top to the bottom. The data plot 816 illustrates the correlation between power and negative bias voltage, showing that as the negative bias voltage increases, power also increases. The DC bias as a function of RF power curve can be used by the controller to adjust a plasma processing parameter to achieve a desired process result on a substrate.

In other embodiments, measurements from the sensor 502 may be used to control the magnitude and phase of RF generators 171, and high voltage DC supply 173.

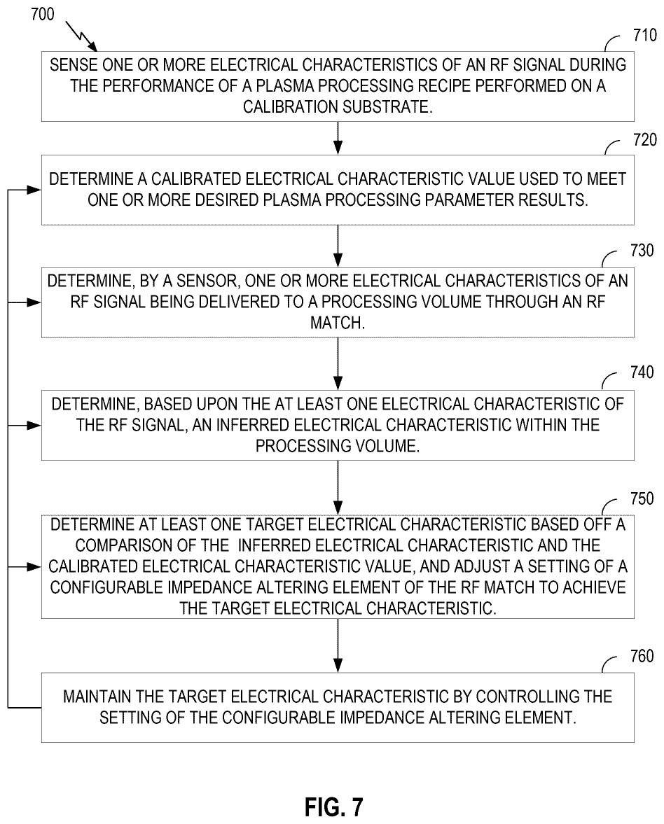

FIG. 7 is a process flow diagram illustrating a method 700 for processing a substrate in a plasma processing system, in accordance with certain embodiments of the present disclosure. The method 700 can be performed by a plasma processing system, such as the plasma processing system described with respect to FIGS. 1A-1B. Method 700 may also be understood by reference to FIGS. 6A-6B.

At operation 710 of method 700, the plasma processing system senses one or more electrical characteristics of an RF signal during the performance of a plasma processing recipe performed on a calibration substrate disposed within the processing volume of a processing chamber 10. The plasma processing system senses (e.g., via one or more sensors 502 electrically coupled between the RF match 172 output and the processing volume) one or more electrical characteristics of the RF signal to determine a voltage and/or current values that are being delivered through the transmission line coupled at the output of the RF match within the processing chamber 10. The measured voltage and/or current values and two-port network transformation technique can then be used to determine one or more inferred real-time electrical characteristics at an electrode within the electrostatic chuck (ESC) assembly, and thus an inferred electrical characteristic at the surface of the substrate.

The calibration substrate is thus used to detect the magnitude of at least one plasma processing parameter, such as ion flux, DC bias, etch rate, heat flux, power transfer level, etch uniformity, or combination thereof while varying a configurable impedance altering element of the impedance matching network and logging the measured voltage, current and/or impedance value corresponding to the at least one substrate metric during one or more steps of a plasma processing recipe that is being performed in the processing volume.

It has been found that the plasma processing parameter(s) detected at different measured voltage, current and/or impedance values and transformed to the electrode within the substrate support, by the two-port network transformation techniques, can have a higher or lower value versus a value of the same the plasma processing parameter(s) at a different measured voltage, current and/or impedance value. The detected magnitude of the plasma processing parameters, its associated measured voltage, current and/or impedance value and any desired process recipe data (e.g., one or more process variable settings (e.g., chemistry, DC power, RF power, RF signal characteristics, gas or vacuum pressures, and/or component, chamber, or substrate temperatures), configuration of the RF Match 172 impedance matching network 620, recipe type, recipe name, etc.) can be stored in memory of the system controller as a calibrated electrical characteristic value, and used in one or more of the subsequent operations discussed below to achieve an improved process result on a substrate 120.

At operation 720, the plasma processing system determines a calibrated electrical characteristic value used to meet one or more desired plasma processing parameter results. For example, the plasma processing parameters achieved on a processed calibration substrate, which were measured at during operations 710, the collected data (e.g., RF signal electrical characteristics) and process recipe data may be used to control subsequent substrate processes and/or stored in memory. In one example, the attributes, can include the one or more plasma processing parameters, such as etch rate, etch profile distortion, or etch rate uniformity associated with the calibration substrate. During operation 720, the process results and process data collected during operation 710 during operation 710 may be used to determine a target plasma impedance 602 that corresponds to a particular magnitude of at least one plasma processing parameter.

At operation 730 of method 700, the plasma processing system measures (e.g., via one or more sensors 502 electrically coupled between the RF match 172 output and the processing volume) one or more electrical characteristics of the RF signal being delivered to the processing volume through the transmission line. The one or more electrical characteristics of the RF signal to be measured may include voltage, current, phase, harmonics, reflected power, spectral component, or similar.

At operation 740, the plasma processing system uses the measurements of the at least one electrical characteristic of the RF signal to determine an inferred electrical characteristic (e.g., a voltage and/or current value), via the two-port network transformation technique, one or more inferred real-time electrical characteristics at an electrode within the electrostatic chuck (ESC) assembly and surface of the substrate.

At operation 750 of method 700, the plasma processing system compares the measured inferred real-time electrical characteristics determined in operation 740 to the calibrated electrical characteristic value determined in operation 720. Based upon the comparison of the inferred real-time electrical characteristic to the calibrated electrical characteristic value, the plasma processing system determines a target electrical characteristic to achieve at least one desired plasma processing parameter result. Using the target electrical characteristic, a configuration for the impedance matching network of the RF Match 172 which will be determined to achieve the target electrical characteristic. The configuration of the impedance matching network includes include a determination of a setting of a configurable impedance altering element for the RF Match 172 that will reduce the difference between the inferred real-time electrical characteristic and the calibrated electrical characteristic value by adjusting the configurable impedance altering element to achieve the target electrical characteristic.

As an example, recalling FIGS. 6A and 6B, in some embodiments, the inferred real-time electrical characteristic may be the measured plasma impedance value 601, the calibrated electrical characteristic value may be the target plasma impedance value 602, and determination and adjustment (illustrated by arrow 603) of a setting of a configurable impedance altering element (e.g., capacitor 622).

Operation 760 of method 700 includes maintaining the measured inferred real-time electrical characteristic at about the target inferred real-time electrical characteristic. Maintaining the measured inferred real-time electrical characteristic at about the target inferred real-time electrical characteristic may include repeating any of the previous operations of method 700.

### Additional Considerations

As used herein, “a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation.

Similarly, “a memory,” “at least one memory” or “one or more memories” generally refers to a single memory configured to store data and/or computer-readable instructions, multiple memories configured to collectively store computer-readable data and/or computer-readable instructions, either a transitory or non-transitory form. Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems may generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. The following claims are not intended to be limited to the embodiments provided but rather are to be accorded the full scope consistent with the language of the claims.

What is claimed is:

1. A method of processing a substrate, comprising:
delivering, by an RF generator, an RF signal to a processing volume of a processing chamber, wherein the delivering of the RF signal further comprises passing the RF signal through an RF match, wherein the RF match includes at least one configurable impedance altering element;
measuring in real-time, by a sensor coupled to a transmission line disposed at an output of the RF match and a distance from an electrode disposed within the processing volume, at least one electrical characteristic of the RF signal;
determining in real-time, at least one target electrical characteristic based upon a comparison between a calibrated electrical characteristic value and the measured electrical characteristic of the RF signal, wherein in the calibrated electrical characteristic value is selected to achieve at least one desired plasma processing parameter result;
adjusting in real-time, a setting of the configurable impedance altering element of the RF match to achieve the target electrical characteristic based on the comparison; and
maintaining in real-time, the target electrical characteristic by controlling the setting of the configurable impedance altering element of the RF match.

2. The method of claim 1, wherein the calibrated electrical characteristic value is stored in a memory of a controller.

3. The method of claim 1, further comprising adjusting in real-time, the RF signal to achieve the target electrical characteristic.

4. The method of claim 1, further comprising:
determining in real-time, one or more process variable settings corresponding to the calibrated electrical characteristic value of the RF signal; and
storing the one or more process variable settings in a memory of a controller.

5. The method of claim 1, further comprising adjusting in real-time, one or more process variable settings to achieve the target electrical characteristic.

6. The method of claim 1, wherein the measuring in real-time of at least one electrical characteristic of the RF signal comprises measuring a voltage, current, phase, frequency, spectral component, harmonic, or combination thereof.

7. The method of claim 1, wherein the sensor is disposed within the RF match.

8. The method of claim 1, wherein the at least one desired plasma processing parameter result comprises an increase, or a reduction, of an etch rate, an ion flux, a heat flux, a power transfer level, a etch uniformity, or combination thereof.

9. The method of claim 1, wherein the setting of the configurable impedance altering element of the RF match differs from a setting of the configurable impedance altering element providing a maximum power transfer.

10. The method of claim 1, wherein the setting of the configurable impedance altering element of the RF match is a setting providing a maximum power transfer.

11. The method of claim 1, wherein determining the calibrated electrical characteristic value comprises a use of a calibration substrate that is disposed within the processing volume and is configured to detect one or more plasma processing parameters, wherein the one or more plasma processing parameters correlate to the at least one desired plasma processing parameter result.

12. A plasma processing system, comprising:
a processing chamber;
a processing volume disposed within the processing chamber;
a radio frequency (RF) generator configured to deliver an RF signal;
an RF match, wherein the RF match includes at least one configurable impedance altering element
a sensor, wherein the sensor is coupled to a transmission line disposed at an output of the RF match and a distance from an electrode disposed within the processing volume;
at least one controller comprising a memory that includes computer-readable instructions stored therein, and the computer-readable instructions, when executed, in real-time, by a processor of the controller, cause:
a delivery, by the RF generator, of the RF signal to the processing volume, wherein the delivery of the RF signal further comprises passing the RF signal through the RF match;
a measurement in real-time, by the sensor, of at least one electrical characteristic of the RF signal;
a determination in real-time, of at least one target electrical characteristic based upon a comparison between a calibrated electrical characteristic value and the measured electrical characteristic of the RF signal, wherein in the calibrated electrical characteristic value is selected to achieve at least one desired plasma processing parameter result;
an adjustment in real-time, of a setting of an impedance altering element of the RF match to achieve the target electrical characteristic; and
maintenance in real-time, of the target electrical characteristic by controlling the setting of the impedance altering element of the RF match.

13. The plasma processing system of claim 12, further comprising a storage, of the calibrated electrical characteristic value, in the memory of the controller.

14. The plasma processing system of claim 12, further comprising an adjustment in real-time, of the RF signal to achieve the target electrical characteristic.

15. The plasma processing system of claim 12, further comprising:
a determination in real-time, of one or more process variable settings corresponding to the calibrated electrical characteristic value of the RF signal; and
storage, of the one or more process variable settings, in the memory of the controller.

16. The plasma processing system of claim 12, further comprising an adjustment in real-time, of one or more process variable settings to achieve the target electrical characteristic.

17. The plasma processing system of claim 12, wherein the measurement in real-time of at least one electrical characteristic of the RF signal comprises a measurement of a voltage, current, phase, frequency, spectral component, harmonic, or combination thereof.

18. The plasma processing system of claim 12, wherein the sensor is disposed within the RF match.
